(19) United States
(12) Patent Application Publication
(10) Pub. No.: US 2026/0136925 A1
(43) Pub. Date: May 14, 2026

(54) SEMICONDUCTOR MODULE AND ELECTRONIC DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Rintaro ASAI, Nisshin-shi (JP); Masaki AOSHIMA, Nisshin-shi (JP)

(21) Appl. No.: 19/361,203

(22) Filed: Oct. 17, 2025

(30) Foreign Application Priority Data
Nov. 11, 2024 (JP) 2024-196814

(51) Int. Cl. H01L 23/367; H01L 23/31; H01L 23/427; H01L 23/482; H01L 23/538; H01L 25/07

(52) U.S. Cl. CPC H10W 40/22; H10W 20/40; H10W 40/73; H10W 70/611; H10W 70/685; H10W 74/114; H10W 90/00

(57) ABSTRACT

A semiconductor module includes: a first semiconductor chip and a second semiconductor chip, each formed with a switching element; a first heat sink disposed adjacent to a second surface of the semiconductor module with respect to the first semiconductor chip, and on which the first semiconductor chip is mounted; a second heat sink disposed adjacent to the second surface with respect to the second semiconductor chip, and on which the second semiconductor chip is mounted; an encapsulating member encapsulating the first and second semiconductor chips; a first heat dissipation wiring layer disposed adjacent to a first surface of the semiconductor module with respect to the first semiconductor chip and thermally connected to the first semiconductor chip; and a second heat dissipation wiring layer disposed adjacent to the first surface with respect to the second semiconductor chip and thermally connected to the second semiconductor chip.

### CROSS REFERENCE TO RELATED APPLICATION

The present application claims the benefit of priority from Japanese Patent Application No. 2024-196814 filed on Nov. 11, 2024. The entire disclosures of the above application are incorporated herein by reference.

### TECHNICAL FIELD

The present disclosure relates to a semiconductor module and an electronic device.

### BACKGROUND

Conventionally, semiconductor modules in which semiconductor elements are encapsulated with a molding resin have been proposed. Such a semiconductor module is, for example, disposed in contact with a cooler to constitute an electronic device. In such an electronic device, since the semiconductor module is in contact with the cooler, heat generated from a semiconductor element is dissipated to the cooler.

### SUMMARY

According to an aspect of the present disclosure, a semiconductor module has a first surface and a second surface opposite to the first surface in a thickness direction and is capable of being disposed on a cooling device so that the first surface and the second surface are sandwiched between two connection pipes of the cooling device. The semiconductor module may include: a first semiconductor chip and a second semiconductor chip, each formed with a switching element; a first heat sink disposed adjacent to the second surface with respect to the first semiconductor chip, and on which the first semiconductor chip is mounted; a second heat sink disposed adjacent to the second surface with respect to the second semiconductor chip, and on which the second semiconductor chip is mounted; an encapsulating member encapsulating the first semiconductor chip and the second semiconductor chip; a first heat dissipation wiring layer disposed adjacent to the first surface with respect to the first semiconductor chip and thermally connected to the first semiconductor chip; and a second heat dissipation wiring layer disposed adjacent to the first surface with respect to the second semiconductor chip and thermally connected to the second semiconductor chip.

### BRIEF DESCRIPTION OF DRAWINGS

FIG. 1 is a front view of an electronic device according to a first embodiment;

FIG. 2 is a cross-sectional view of a semiconductor module;

FIG. 3 is a plan view showing wiring layers on a second encapsulating member of the semiconductor module;

FIG. 4 is a plan view showing wiring layers on a first encapsulating member of the semiconductor module;

FIG. 5 is a diagram showing a circuit configuration of the semiconductor module;

FIG. 6 is a cross-sectional view of a semiconductor module according to a second embodiment;

FIG. 7 is a plan view showing wiring layers on a second encapsulating member of the semiconductor module;

FIG. 8 is a plan view showing wiring layers on a first encapsulating member of the semiconductor module; and

FIG. 9 is a cross-sectional view of a semiconductor module including a bonding member according to a third embodiment.

### DETAILED DESCRIPTION

The inventors of the present disclosure have been studying a semiconductor module including a first semiconductor chip and a second semiconductor chip connected in series. Specifically, in such a semiconductor module, the first semiconductor chip is disposed on a first heat sink, and the second semiconductor chip is disposed on a second heat sink.

Further, the inventors of the present disclosure are considering making this semiconductor module into an electronic device by bringing both ends of the semiconductor module into contact with the coolers in a stacking direction of the first semiconductor chip and the first heat sink. In other words, the inventors are considering constructing the electronic device in which the semiconductor module is arranged so as to be sandwiched between the coolers.

In such a semiconductor module, since the first heat sink and the second heat sink are provided, heat dissipation to the cooler disposed on the side adjacent to the first and second heat sinks is enhanced. However, heat dissipation to the cooler disposed on the opposite side from the first and second heat sinks may be low. In other words, in this semiconductor module, there is a possibility that double-sided heat dissipation properties may be reduced.

The present disclosure provides a semiconductor module and an electronic device, which are capable of double-sided heat dissipation.

According to an aspect of the present disclosure, a semiconductor module has a first surface and a second surface opposite to the first surface in a thickness direction, and is capable of being disposed on a cooling device so that the first surface and the second surface are sandwiched between two connection pipes of the cooling device. The semiconductor module includes a first semiconductor chip, a second semiconductor chip, a first heat sink, a second heat sink, an encapsulating member, a first heat dissipation wiring layer, and a second heat dissipation wiring layer. The first semiconductor chip and the second semiconductor chip each formed with a semiconductor element. The first heat sink is disposed adjacent to the second surface with respect to the first semiconductor chip, and the first semiconductor chip is disposed on the first heat sink. The second heat sink is disposed adjacent to the second surface with respect to the second semiconductor chip, and the second semiconductor chip is disposed on the second heat sink. The encapsulating member encapsulates the first semiconductor chip and the second semiconductor chip. The first heat dissipation wiring layer is disposed adjacent to the first surface with respect to the first semiconductor chip and thermally connected to the first semiconductor chip. The second heat dissipation wiring layer is disposed adjacent to the first surface with respect to the second semiconductor chip and thermally connected to the second semiconductor chip.

In such a configuration, the first heat sink and the second heat sink are disposed on the second surface side of the semiconductor module, while the first heat dissipation wiring layer and the second heat dissipation wiring layer are disposed on the first surface side of the semiconductor module. In other words, the first heat sink and the first heat dissipation wiring layer are disposed on opposite sides of the first semiconductor chip in the thickness direction, and the second heat sink and the second heat dissipation wiring layer are disposed on opposite sides of the second semiconductor chip in the thickness direction. Therefore, when the semiconductor module is arranged between the two connection pipes of the cooling device such that the first surface and the second surface face the two connection pipes, respectively, heat generated from the first and second semiconductor chips can be dissipated to both of the two connection pipes disposed on the opposite sides of the semiconductor module. In other words, heat can be dissipated from both sides of the semiconductor module.

According to another aspect of the present disclosure, an electronic device includes: the semiconductor module described above; and the cooling device that has a flow path through which a cooling medium for cooling the semiconductor module flows therein. The cooling device includes an inflow pipe to introduce the cooling medium into the flow path, an outflow pipe to discharge the cooling medium from the flow path, and a plurality of connection pipes that connect the inflow pipe and the outflow pipe. The semiconductor module is disposed so as to be sandwiched between two of the connection pipes, so that the first heat sink and the second heat sink face one of the two connection pipes located on the second surface side, and the first heat dissipation wiring layer and the second heat dissipation wiring layer face the other of the two connection pipes located on the first surface side.

In such a semiconductor device, the first heat sink and the second heat sink are disposed in positions facing one of the two connection pipes, and the first heat dissipation wiring layer and the second heat dissipation wiring layer are disposed in positions facing the other of the two connection pipes. Therefore, the semiconductor module can efficiently dissipate heat generated from the first semiconductor chip and heat generated from the second semiconductor chip to both of the two connection pipes disposed on the opposite sides thereof.

Hereinafter, embodiments of the present disclosure will be described with reference to the drawings. In the following descriptions, the same or equivalent parts are denoted by the same reference numerals throughout the embodiments.

### First Embodiment

A first embodiment will be described with reference to the drawings. In the following, a power conversion device will be described as an example of an electronic device. Such an electronic device is suitable for use, for example, in vehicles.

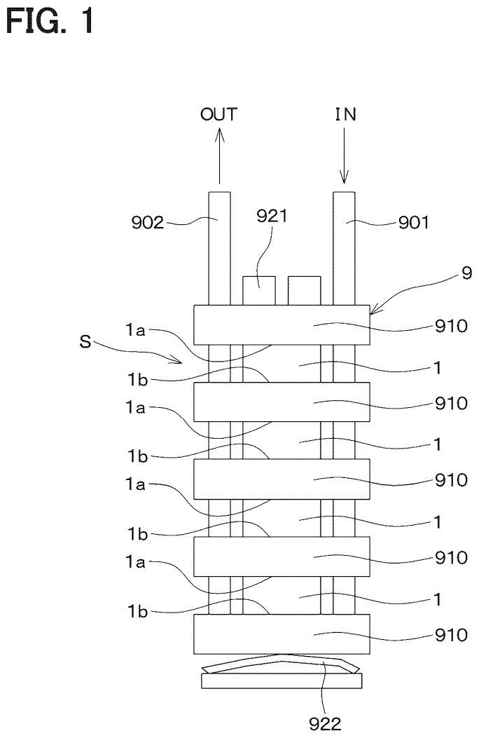

As shown in FIG. 1, an electronic device S of the present embodiment includes a semiconductor module 1 and a cooling device 9 for cooling the semiconductor module 1.

The cooling device 9 is configured to circulate a cooling medium such as cooling water inside thereof. The cooling device 9 includes an inflow pipe 901, an outflow pipe 902, and a connection pipe 910. The inflow pipe 901 and the outflow pipe 902 form circular flow paths therein. The connection pipe 910 is in communication with the inflow pipe 901 and the outflow pipe 902, and forms a substantially rectangular flow path. Specifically, the inflow pipe 901 and the outflow pipe 902 are arranged so as to extend in the same direction. The connection pipe 910 has a substantially rectangular shape in a plan view, and its lengthwise direction is defined as a longitudinal direction. A plurality of the connection pipes 910 are arranged along the extending direction of the inflow pipe 901 and the outflow pipe 902, and the inflow pipe 901 and the outflow pipe 902 are disposed to pass through opposite ends in the longitudinal direction of each of the connection pipes 910. In the present embodiment, five connection pipes 910 are provided so as to form four spaces in an arrangement direction of the connection pipes 910. The arrangement direction of the connection pipes 910 corresponds to the extending direction of the inflow pipe 901 and the outflow pipe 902, and also corresponds to the vertical direction in FIG. 1. Hereinafter, the arrangement direction of the connection pipes 910 will be simply referred to as the arrangement direction. In addition, the connection pipe 910 located at one end in the arrangement direction (e.g., the lowermost connection pipe 910 in FIG. 1) has a closed portion on the side opposite to the side to which the inflow pipe 901 and the outflow pipe 902 are coupled.

In the present embodiment, the semiconductor module 1 constitutes an inverter circuit. As will be described later, the semiconductor module 1 includes a first semiconductor chip 31 constituting an upper arm UA and a second semiconductor chip 32 constituting a lower arm LA. The specific configuration of the semiconductor module 1 will be described later.

The semiconductor module 1 is disposed on the cooling device 9 so as to be thermally connected to both of a pair of connection pipes 910 that are disposed on opposite sides in the arrangement direction. Specifically, the semiconductor module 1 is disposed on the cooling device 9 such that one surface 1a side and the other surface 1b side in the thickness direction, respectively, face the connection pipes 910. In the present embodiment, the one surface 1a corresponds to a first surface, and the other surface 1b corresponds to a second surface.

In the present embodiment, the cooling device 9 has a fixing member 921 that is fixed to the connection pipe 910 located at the end on the other side in the arrangement direction (e.g., the uppermost connection pipe 910 in FIG. 1). The fixing member 921 is fixed to the connection pipe 910 as being connected by a housing or the like (not shown). In other words, the connection pipe 910 located at the end on the other side in the arrangement direction is in a state of being difficult to displace. In addition, the cooling device 9 has an elastic member 922, which is made of a spring or the like. The elastic member 922 is disposed to be in contact with the connection pipe 910 located at the end on the one side in the arrangement direction (e.g., the lowermost connection pipe 910 in FIG. 1). The elastic member 922 is capable of pressing the connection pipe 910 in the arrangement direction. In the present embodiment, by pressing the connection pipe 910 in the arrangement direction with the elastic member 922, it is possible to reduce a gap between the semiconductor module 1 and the connection pipe 910.

In such a cooling device 9, the cooling medium such as a cooling water is introduced into the inflow pipe 901, flows through the connection pipes 910, and is discharged from the outflow pipe 902, so that the semiconductor modules 1 attached to the cooling device 9 are cooled. Although details are omitted, in the cooling device 9 of the present embodiment, the cooling medium discharged from the outflow pipe 902 is introduced into the inflow pipe 901 via a radiator or the like. In other words, the cooling device 9 is configured to circulate the cooling medium therethrough.

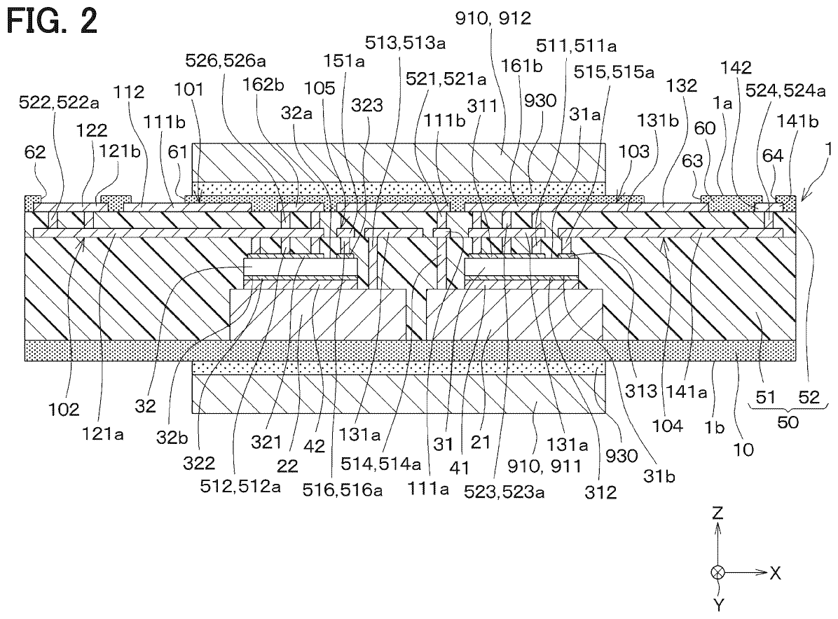

Next, the configuration of the semiconductor module 1 of the present embodiment will be described with reference to FIGS. 2 to 5. Hereinafter, one direction will be referred to as an X-axis direction, and a direction perpendicular to the X-axis direction will be referred to as a Y-axis direction. Also, a direction perpendicular to both the X-axis and Y-axis directions will be referred to as a Z-axis direction. The X-axis direction can also be referred to as a first direction, and the Y-axis direction can also be referred to as a second direction. Also, the Z-axis direction can also be referred to as a third direction. In addition, the Z-axis direction corresponds to the thickness direction of the semiconductor module 1. Hereinafter, of the two connection pipes 910 sandwiching the semiconductor module 1, the connection pipe 910 disposed adjacent to an insulating heat dissipation sheet 10 of the semiconductor module 1 will be referred to as a first connection pipe 911, and the connection pipe 910 disposed adjacent to an insulating heat dissipation sheet 60 of the semiconductor module 1 will be referred to as a second connection pipe 912. The insulating heat dissipation sheets 10 and 60 will be described later in detail. In the present embodiment, the first connection pipe 911 corresponds to one of the two connection pipes, and the second connection pipe 912 corresponds to the other of the two connection pipes.

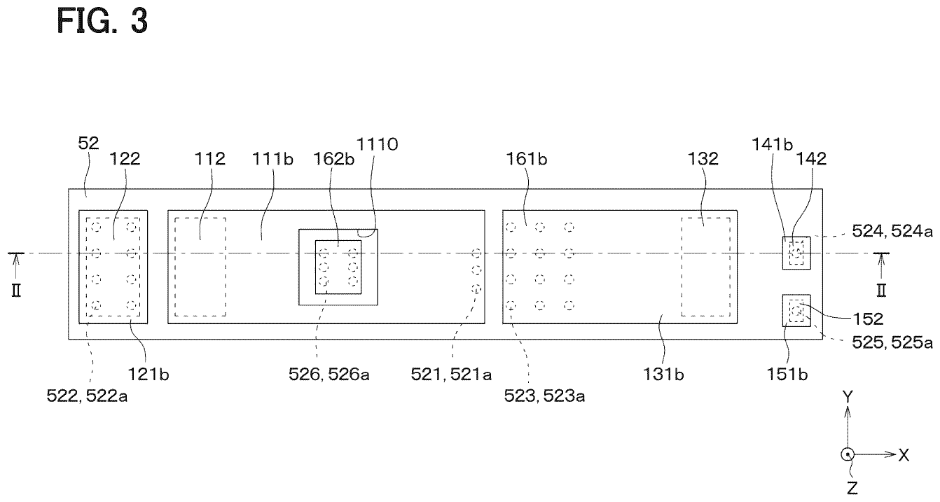

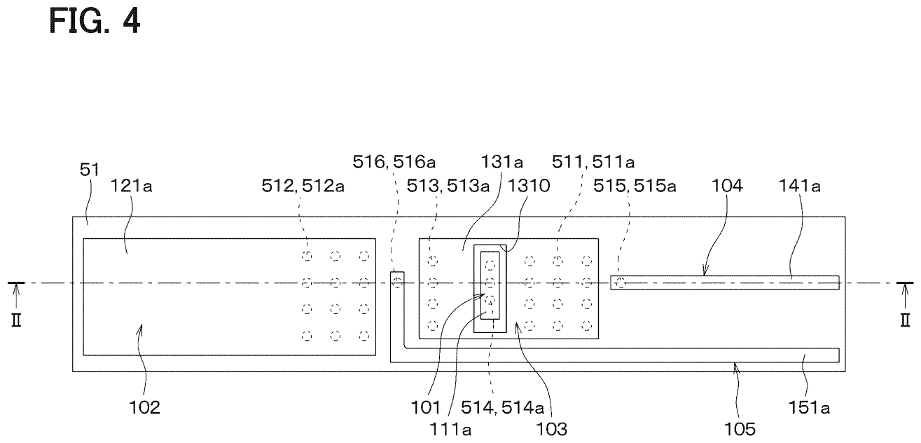

In the present embodiment, the semiconductor module 1 has a substantially rectangular shape as a planar shape. The semiconductor module 1 includes the insulating heat dissipation sheet 10, a first heat sink 21, a second heat sink 22, a first semiconductor chip 31, a second semiconductor chip 32, an encapsulating member 50, first to third wiring portions 101 to 103, first and second gate wiring portions 104 and 105, and the like. FIG. 2 corresponds to a cross-sectional view taken along a line II-II in FIGS. 3 and 4.

The insulating heat dissipation sheet 10 is, for example, a planar rectangular sheet made of an epoxy resin containing a filler or the like. The insulating heat dissipation sheet 10 has a thermal conductivity higher than that of the encapsulating member 50 described later. In the semiconductor module 1 of the present embodiment, the insulating heat dissipation sheet 10 provides the other surface 1b of the semiconductor module 1 in the thickness direction (i.e., in the Z-axis direction), and the other surface 1b is disposed on the first connection pipe 911 through a bonding member 930.

The first heat sink 21 and the second heat sink 22 each have a block shape, and are made of copper or the like. In the present embodiment, the first heat sink 21 and the second heat sink 22 each have a planar rectangular shape. The first heat sink 21 and the second heat sink 22 have the same size, and the equal thickness. Here, the terms “equal” and “same” include minor manufacturing tolerances. The first heat sink 21 and the second heat sink 22 are arranged side by side on the insulating heat dissipation sheet 10. In the present embodiment, the first heat sink 21 and the second heat sink 22 are arranged side by side along the X-axis direction. Further, the first heat sink 21 and the second heat sink 22 are disposed in a region of the insulating heat dissipation sheet 10, the region facing the first connection pipe 911.

The first semiconductor chip 31 and the second semiconductor chip 32 are each formed with a semiconductor element such as a switching element and/or a diode element for freewheeling. Examples of the switching element include a metal oxide semiconductor field effect transistor (MOSFET) element and an insulated gate bipolar transistor (IGBT) element.

In the present embodiment, the first semiconductor chip 31 has a first electrode 311 on one surface 31a side and a second electrode 312 on the other surface 31b side. The first semiconductor chip 31 is formed with the semiconductor element so as to allow current to flow between the first electrode 311 and the second electrode 312. The first semiconductor chip 31 has a gate pad 313 on the one surface 31a side. The gate pad 313 is connected to a gate electrode of the switching element, such as the MOSFET element or the IGBT element.

Similarly, the second semiconductor chip 32 has a first electrode 321 on one surface 32a side, and a second electrode 322 on the other surface 32b side. The second semiconductor chip 32 is formed with the semiconductor element so as to allow current to flow between the first electrode 321 and the second electrode 322. The second semiconductor chip 32 has a gate pad 323 on the one surface 32a side. The gate pad 323 is connected to a gate electrode of the switching element, such as the MOSFET element or the IGBT element.

The first semiconductor chip 31 is disposed on the first heat sink 21, and the second electrode 312 is bonded to the first heat sink 21 through a first bonding member 41. The second semiconductor chip 32 is disposed on the second heat sink 22, and the second electrode 322 is bonded to the second heat sink 22 through a second bonding member 42. In the present embodiment, the first heat sink 21 and the first semiconductor chip 31 are stacked so that the stacking direction thereof corresponds to the Z-axis direction. Also, the second heat sink 22 and the second semiconductor chip 32 are stacked so that the stacking direction thereof corresponds to the Z-axis direction.

The first bonding member 41 is made of a material that electrically and thermally connects the first semiconductor chip 31 and the first heat sink 21. For example, the first bonding member 41 is made of a solder, a silver sintered body, or the like. The second bonding member 42 is made of a material that electrically and thermally connects the second semiconductor chip 32 and the second heat sink 22. For example, the second bonding member 42 is made of a solder, a silver sintered body, or the like. Since the first semiconductor chip 31 is disposed on the first heat sink 21 in this manner, heat generated from the first semiconductor chip 31 is dissipated from the first heat sink 21 to the first connection pipe 911 through the insulating heat dissipation sheet 10. Likewise, since the second semiconductor chip 32 is disposed on the second heat sink 22 in this manner, heat generated from the second semiconductor chip 32 is dissipated from the second heat sink 22 to the first connection pipe 911 through the insulating heat dissipation sheet 10.

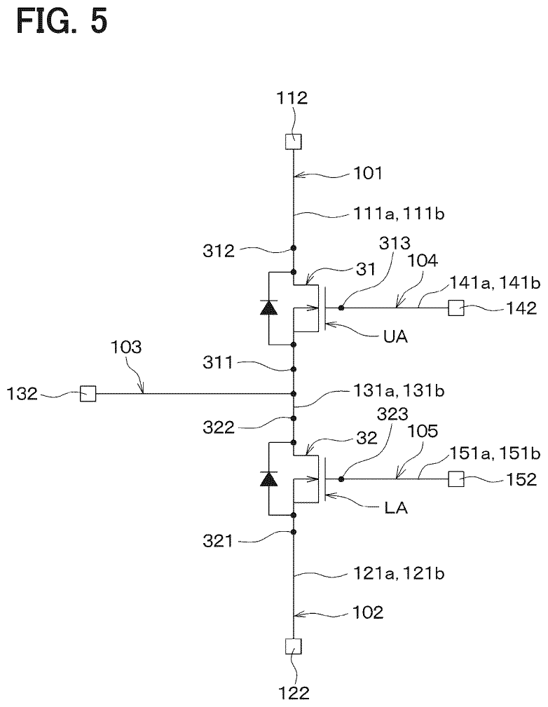

The first semiconductor chip 31 and the second semiconductor chip 32 of the present embodiment are used as being connected in series so as to constitute the upper arm UA and the lower arm LA of the inverter circuit, for example, as shown in FIG. 5. Specifically, the first semiconductor chip 31 is used to constitute the upper arm UA, so that the second electrode 312 is connected to the first wiring portion 101 and the first electrode 311 is connected to the third wiring portion 103. In addition, the gate pad 313 of the first semiconductor chip 31 is connected to the first gate wiring portion 104.

The second semiconductor chip 32 is used to constitute the lower arm LA, so that the second electrode 322 is connected to the third wiring portion 103 and the first electrode 321 is connected to the second wiring portion 102. In addition, the gate pad 323 of the second semiconductor chip 32 is connected to the second gate wiring portion 105.

The first wiring portion 101 serves as a so-called P wiring, the second wiring portion 102 serves as a so-called N wiring, and the third wiring portion 103 serves as a so-called O wiring. As will be described later, the first wiring portion 101 includes a first wiring portion first wiring layer 111a, a first wiring portion second wiring layer 111b, and a first terminal portion 112. The second wiring portion 102 includes a second wiring portion first wiring layer 121a, a second wiring portion second wiring layer 121b, and a second terminal portion 122. The third wiring portion 103 includes a third wiring portion first wiring layer 131a, a third wiring portion second wiring layer 131b, and a third terminal portion 132. The first gate wiring portion 104 includes a first gate wiring portion first wiring layer 141a, a first gate wiring portion second wiring layer 141b, and a first gate terminal portion 142. The second gate wiring portion 105 includes a second gate wiring portion first wiring layer 151a, a second gate wiring portion second wiring layer 151b, and a second gate terminal portion 152. Although not specifically shown, the third wiring portion 103 is connected to an external load or the like. In such a circuit configuration, the switching elements of the first semiconductor chip 31 and the second semiconductor chip 32 are alternately turned on.

As shown in FIG. 2, the encapsulating member 50 is disposed on the insulating heat dissipation sheet 10 so as to encapsulate the first semiconductor chip 31, the second semiconductor chip 32, the first heat sink 21, the second heat sink 22, and the like. In the present embodiment, the encapsulating member 50 is formed by a stack of a plurality of film members, which are made of resin, such as prepreg, and are integrated by being pressed together under heating. A part of the encapsulating member 50 and the like disposed between the first heat sink 21 and the second heat sink 22 is placed as the resin material constituting the film members flows therebetween, when the film members are integrated by being pressed together under heating.

In the present embodiment, a part of the encapsulating member 50 that is disposed on the insulating heat dissipation sheet 10 and encapsulates the first and second semiconductor chips 31 and 32, the first and second heat sinks 21 and 22, and the like will be hereinafter referred to as a first encapsulating member 51. Also, a part of the encapsulating member 50 disposed on top of the first encapsulating member 51 will be hereinafter referred to as a second encapsulating member 52.

As shown in FIGS. 2 to 4, the first to third wiring portions 101 to 103 are appropriately arranged on the first encapsulating member 51 and the second encapsulating member 52, so that the first semiconductor chip 31 and the second semiconductor chip 32 constitute the upper arm UA and the lower arm LA, respectively. In other words, in the present embodiment, the first to third wiring portions 101 to 103 are collectively arranged on the same side of the semiconductor module 1 with respect to the first semiconductor chip 31 and the second semiconductor chip 32, that is, above the first semiconductor chip 31 and the second semiconductor chip 32, as shown in FIG. 2. Also, the first gate wiring portion 104 and the second gate wiring portion 105 are appropriately arranged on the first encapsulating member 51 or the second encapsulating member 52. The first to third wiring portions 101 to 103 and the first and second gate wiring portions 104 and 105 are made of, for example, aluminum wirings or copper wirings.

Specifically, the first encapsulating member 51 is formed with a first chip via hole 511 that exposes the first electrode 311 of the first semiconductor chip 31. The first encapsulating member 51 is formed with a second chip via hole 512 that exposes the first electrode 321 of the second semiconductor chip 32. The first encapsulating member 51 is formed with a second heat sink via hole 513 that exposes a portion of the second heat sink 22, the portion being adjacent to the first heat sink 21. The first encapsulating member 51 is formed with a first heat sink via hole 514 that exposes a portion of the first heat sink 21, the portion being adjacent to the second heat sink 22. The first encapsulating member 51 is formed with a first gate via hole 515 that exposes the gate pad 313 of the first semiconductor chip 31. The first encapsulating member 51 is formed with a second gate via hole 516 that exposes the gate pad 323 of the second semiconductor chip 32. Each of the via holes 511 to 516 includes one or more holes.

The third wiring portion 103 has the third wiring portion first wiring layer 131a that is disposed on the first encapsulating member 51 so as to face the first semiconductor chip 31 and the portion of the second heat sink 22 adjacent to the first heat sink 21. The third wiring portion first wiring layer 131a is connected to the first electrode 311 of the first semiconductor chip 31 through a first chip via 511a that is disposed in the first chip via hole 511. The third wiring portion first wiring layer 131a is also connected to the second heat sink 22 through a second heat sink via 513a that is disposed in the second heat sink via hole 513, and is thus connected to the second electrode 322 of the second semiconductor chip 32 through the second heat sink 22. In the present embodiment, the third wiring portion first wiring layer 131a is formed with a hole 1310 at a position that faces the portion of the first heat sink 21 adjacent to the second heat sink 22. The first chip via 511a and the second heat sink via 513a are made of, for example, copper vias or the like. Similarly, each of the vias described later is also made of copper via or the like.

The second wiring portion 102 has the second wiring portion first wiring layer 121a that is disposed on the first encapsulating member 51 so as to face the second heat sink 22 and the second semiconductor chip 32. The second wiring portion first wiring layer 121a is connected to the first electrode 321 of the second semiconductor chip 32 through a second chip via 512a that is disposed in the second chip via hole 512. The second wiring portion first wiring layer 121a is formed so as to extend toward the side opposite to the third wiring portion first wiring layer 131a.

The first wiring portion 101 has the first wiring portion first wiring layer 111a that is disposed on the first encapsulating member 51 so as to face a portion of the first heat sink 21, the portion being adjacent to the second heat sink 22. In the present embodiment, the first wiring portion first wiring layer 111a is disposed within the hole 1310 formed in the third wiring portion first wiring layer 131a. The first wiring portion first wiring layer 111a is connected to the first heat sink 21 through a first heat sink via 514a that is disposed in the first heat sink via hole 514, and is thus connected to the second electrode 312 of the first semiconductor chip 31 through the first heat sink 21.

The first gate wiring portion 104 has the first gate wiring portion first wiring layer 141a that is disposed on the first encapsulating member 51 so as to include a portion facing the gate pad 313 of the first semiconductor chip 31. The first gate wiring portion first wiring layer 141a is connected to the gate pad 313 of the first semiconductor chip 31 through a first gate via 515a that is disposed in the first gate via hole 515. The first gate wiring portion first wiring layer 141a is extended toward the side opposite to the third wiring portion first wiring layer 131a.

The second gate wiring portion 105 has the second gate wiring portion first wiring layer 151a that is disposed on the first encapsulating member 51 so as to include a portion facing the gate pad 323 of the second semiconductor chip 32. The second gate wiring portion first wiring layer 151a is connected to the gate pad 323 of the second semiconductor chip 32 through a second gate via 516a that is disposed in the second gate via hole 516. The second gate wiring portion first wiring layer 151a has a substantially L-shape in the plan view so as not to interfere with the second wiring portion first wiring layer 121a and the third wiring portion first wiring layer 131a. The second gate wiring portion first wiring layer 151a is extended toward the side opposite to the second wiring portion first wiring layer 121a.

The second encapsulating member 52 is disposed on the first encapsulating member 51 so as to cover the third wiring portion first wiring layer 131a, the second wiring portion first wiring layer 121a, the first wiring portion first wiring layer 111a, the first gate wiring portion first wiring layer 141a, and the second gate wiring portion first wiring layer 151a. The second encapsulating member 52 is formed with a third wiring portion via hole 523 that exposes the third wiring portion first wiring layer 131a. The second encapsulating member 52 is formed with a second wiring portion via hole 522 that exposes the second wiring portion first wiring layer 121a. The second encapsulating member 52 is formed with a first wiring portion via hole 521 that exposes the first wiring portion first wiring layer 111a. The second encapsulating member 52 is formed with a first gate wiring portion via hole 524 that exposes the first gate wiring portion first wiring layer 141a. The second encapsulating member 52 is formed with a second gate wiring portion via hole 525 that exposes the second gate wiring portion first wiring layer 151a. Each of the via holes 521 to 525 includes one or more holes.

The first wiring portion 101 has the first wiring portion second wiring layer 111b that is disposed on the second encapsulating member 52 so as to face the second wiring portion first wiring layer 121a, while including a portion that faces the first wiring portion first wiring layer 111a. In this manner, by arranging the first wiring portion second wiring layer 111b and the second wiring portion first wiring layer 121a so as to face each other, it is possible to reduce the impedance between the first wiring portion second wiring layer 111b and the second wiring portion first wiring layer 121a when current flows in opposite directions in the first wiring portion second wiring layer 111b and the second wiring portion first wiring layer 121a. In the present embodiment, the first wiring portion 101 is configured to include the first wiring portion second wiring layer 111b, and the second wiring portion 102 is configured to include the second wiring portion first wiring layer 121a. In the present embodiment, therefore, it can be said that the first wiring portion 101 and the second wiring portion 102 have portions that are disposed facing each other. The first wiring portion second wiring layer 111b is connected to the first wiring portion first wiring layer 111a through the first wiring portion via 521a, which is disposed in the first wiring portion via hole 521. Further, the first wiring portion second wiring layer 111b is extended to a position different from the portion facing the second connection pipe 912.

In the present embodiment, the first wiring portion second wiring layer 111b is formed with a hole 1110 in the portion that faces the second connection pipe 912. The first wiring portion second wiring layer 111b is formed with the hole 1110 in the portion that faces the second connection pipe 912 as well as the second semiconductor chip 32.

A second heat dissipation wiring layer 162b is disposed within the hole 1110 on the second encapsulating member 52. In other words, above the second encapsulating member 52, the second heat dissipation wiring layer 162b is disposed in the portion facing the second connection pipe 912. The second heat dissipation wiring layer 162b is connected to the second wiring portion first wiring layer 121a through a second heat dissipation wiring layer via 526a that is disposed in a second heat dissipation wiring layer via hole 526 formed in the second encapsulating member 52. In other words, the second heat dissipation wiring layer 162b is in a state of being thermally connected to the second semiconductor chip 32. Therefore, the heat generated from the second semiconductor chip 32 is dissipated from the second heat dissipation wiring layer 162b toward the second connection pipe 912. It should be noted that the second heat dissipation wiring layer 162b and the first wiring portion second wiring layer 111b are insulated from each other.

The second wiring portion 102 has the second wiring portion second wiring layer 121b that is disposed on the second encapsulating member 52 so as to include a portion facing the second wiring portion first wiring layer 121a. The second wiring portion second wiring layer 121b is connected to the second wiring portion first wiring layer 121a through a second wiring portion via 522a that is disposed in the second wiring portion via hole 522. It should be noted that the second wiring portion second wiring layer 121b is formed at a position different from the portion facing the second connection pipe 912.

The third wiring portion 103 has the third wiring portion second wiring layer 131b that is disposed on the second encapsulating member 52 so as to include a portion facing the third wiring portion first wiring layer 131a. The third wiring portion second wiring layer 131b is connected to the third wiring portion first wiring layer 131a through a third wiring portion via 523a that is disposed in the third wiring portion via hole 523. It should be noted that, in the present embodiment, the third wiring portion second wiring layer 131b is extended from the portion facing the second connection pipe 912 of the cooling device 9 to a position different from the portion facing the second connection pipe 912.

The third wiring portion second wiring layer 131b is also thermally connected to the first semiconductor chip 31 through the third wiring portion first wiring layer 131a. Therefore, in the portion of the third wiring portion second wiring layer 131b that faces the second connection pipe 912, the heat generated from the first semiconductor chip 31 is dissipated to the second connection pipe 912. Accordingly, in the present embodiment, the portion of the third wiring portion second wiring layer 131b that faces the second connection pipe 912 also functions as a first heat dissipation wiring layer 161b that dissipates the heat from the first semiconductor chip 31.

The first gate wiring portion 104 has the first gate wiring portion second wiring layer 141b that is disposed on the second encapsulating member 52 so as to include a portion facing the first gate wiring portion first wiring layer 141a. The first gate wiring portion second wiring layer 141b is connected to the first gate wiring portion first wiring layer 141a through a first gate via 524a that is disposed in the first gate wiring portion via hole 524.

The second gate wiring portion 105 has the second gate wiring portion second wiring layer 151b that is disposed on the second encapsulating member 52 so as to include a portion facing the second gate wiring portion first wiring layer 151a. The second gate wiring portion second wiring layer 151b is connected to the second gate wiring portion first wiring layer 151a through a second gate via 525a that is disposed in the second gate wiring portion via hole 525. It should be noted that the first gate wiring portion second wiring layer 141b and the second gate wiring portion second wiring layer 151b are formed at positions different from the portions facing the second connection pipe 912.

The first terminal portion 112 is configured as a part of the first wiring portion second wiring layer 111b. The second terminal portion 122 is configured as a part of the second wiring portion second wiring layer 121b. The third terminal portion 132 is configured as a part of the third wiring portion second wiring layer 131b. The first gate terminal portion 142 is configured as a part of the first gate wiring portion second wiring layer 141b. The second gate terminal portion 152 is configured as a part of the second gate wiring portion second wiring layer 151b.

Each of the terminal portions 112, 122, 132, 142, and 152 is disposed in a portion different from the portion facing the second connection pipe 912 of the cooling device 9. In the present embodiment, the first terminal portion 112, the second terminal portion 122, and the third terminal portion 132 are arranged in such a manner that, in an alignment direction (i.e., the X-axis direction) of the first semiconductor chip 31 and the second semiconductor chip 32, the first terminal portion 112 is positioned between the third terminal portion 132 and the second terminal portion 122. Further, the first gate terminal portion 142 and the second gate terminal portion 152 are disposed on the side opposite to the first terminal portion 112 and the second terminal portion 122 with respect to the third terminal portion 132 interposed therebetween.

The insulating heat dissipation sheet 60, which is similar to the insulating heat dissipation sheet 10, is disposed on the second encapsulating member 52. The insulating heat dissipation sheet 60 is formed with a contact hole 61 for exposing the first terminal portion 112, a contact hole 62 for exposing the second terminal portion 122, and a contact hole 63 for exposing the third terminal portion 132. The insulating heat dissipation sheet 60 is formed with a contact hole 64 for exposing the first gate terminal portion 142 and a contact hole 65 for exposing the second gate terminal portion 152. The first heat dissipation wiring layer 161b and the second heat dissipation wiring layer 162b are covered with the insulating heat dissipation sheet 60. In the present embodiment, the one surface 1a of the semiconductor module 1 is provided by the insulating heat dissipation sheet 60. That is, in the present embodiment, only the insulating heat dissipation sheet 60 is present between the one surface 1a and the first heat dissipation wiring layer 161b and the second heat dissipation wiring layer 162b.

The semiconductor module 1 of the present embodiment has the configurations as described above. The semiconductor module 1 is disposed on the cooling device 9 so as to be sandwiched between two adjacent connection pipes 910 in the arrangement direction. Specifically, the semiconductor module 1 is arranged so that the one surface 1a and the other surface 1b face the connection pipes 910 through bonding members 930, which are composed of a thermal interface material (TIM) such as grease.

The heat generated from the first semiconductor chip 31 of the semiconductor module 1 is dissipated to the first connection pipe 911 through the first heat sink 21, and is also dissipated to the second connection pipe 912 through the third wiring portion first wiring layer 131a and the first heat dissipation wiring layer 161b. In addition, the heat generated from the second semiconductor chip 32 is dissipated to the first connection pipe 911 through the second heat sink 22, and is also dissipated to the second connection pipe 912 through the second wiring portion first wiring layer 121a and the second heat dissipation wiring layer 162b. In other words, according to the semiconductor module 1 of the present embodiment, a double-sided heat dissipation structure can be achieved, which allows the heat generated from the first semiconductor chip 31 and the second semiconductor chip 32 to be dissipated from both sides in the Z-axis direction.

As described above, the first heat sink 21 and the second heat sink 22 are disposed adjacent to the other surface 1b, while the first heat dissipation wiring layer 161b and the second heat dissipation wiring layer 162b are disposed adjacent to the one surface 1a. In other words, the first heat sink 21 and the first heat dissipation wiring layer 161b are disposed on opposite sides of the first semiconductor chip 31, and the second heat sink 22 and the second heat dissipation wiring layer 162b are disposed on opposite sides of the second semiconductor chip 32 in the Z-axis direction. Therefore, when the semiconductor module 1 is disposed so as to be sandwiched between the first connection pipe 911 and the second connection pipe 912 of the cooling device 9, the heat generated from the first semiconductor chip 31 and the heat generated from the second semiconductor chip 32 can be dissipated from both the one surface 1a side and the other surface 1b side of the semiconductor module 1. In other words, in the semiconductor module 1 of the present embodiment, double-sided heat dissipation is possible. Accordingly, it is possible to suppress the first semiconductor chip 31 and the second semiconductor chip 32 from becoming high in temperature. In addition, in the present embodiment, the first heat sink 21 and the second heat sink 22 are disposed so as to face the first connection pipe 911, and the first heat dissipation wiring layer 161b and the second heat dissipation wiring layer 162b are disposed so as to face the second connection pipe 912. Therefore, the heat generated from the first semiconductor chip 31 and the heat generated from the second semiconductor chip 32 can be efficiently dissipated from the one surface 1a side and the other surface 1b side of the semiconductor module 1.

(1) In the present embodiment, the first heat dissipation wiring layer 161b and the second heat dissipation wiring layer 162b are disposed so as to be covered by the insulating heat dissipation sheet 60, which is positioned closest to the second connection pipe 912. In other words, the first heat dissipation wiring layer 161b and the second heat dissipation wiring layer 162b are disposed such that only the insulating heat dissipation sheet 60 is positioned between the first and second heat dissipation wiring layers 161b and 162b and the one surface 1a of the semiconductor module 1. As such, the first heat dissipation wiring layer 161b and the second heat dissipation wiring layer 162b can be located at the positions closer to the one surface 1a of the semiconductor module 1. Therefore, when the heat from the first heat dissipation wiring layer 161b and the heat from the second heat dissipation wiring layer 162b are dissipated to the cooling device 9, it is possible to restrict the heat dissipation effect from being reduced.

(2) In the present embodiment, the first wiring portion 101 and the second wiring portion 102 are arranged so as to include the portions facing each other. Therefore, the impedance can be reduced. In this configuration, the first heat dissipation wiring layer 161b is configured as the part of the third wiring portion second wiring layer 131b. The second heat dissipation wiring layer 162b is disposed in the hole 1110 formed in the first wiring portion second wiring layer 111b. Therefore, in the present embodiment, it is possible to achieve the double-sided heat dissipation while reducing the impedance.

### Second Embodiment

A second embodiment will be described hereinafter. In the present embodiment, the semiconductor module is configured by adding electronic components relative to the semiconductor module 1 of the first embodiment. The other configurations of the present embodiment are similar to those of the first embodiment, and therefore a description of the similar configurations will not be repeated.

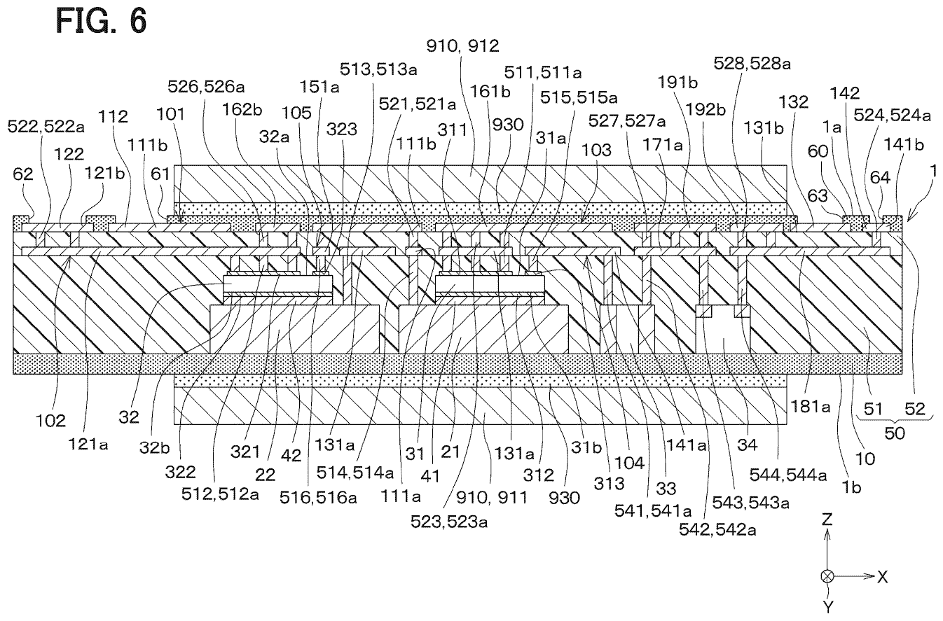

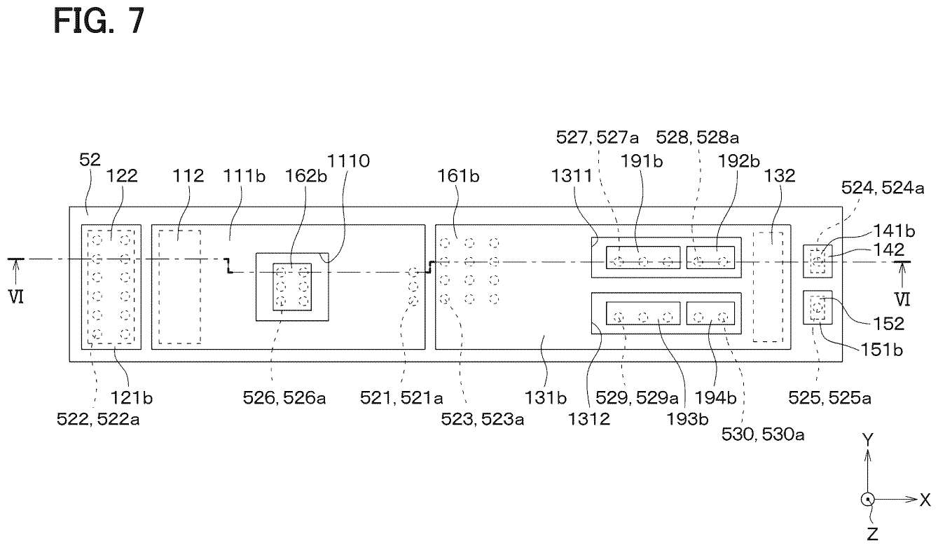

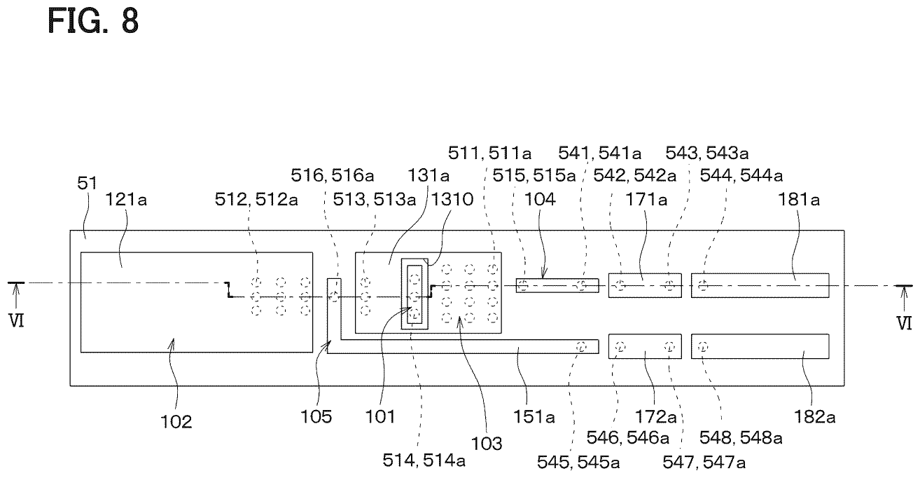

As shown in FIGS. 6 to 8, the semiconductor module 1 of the present embodiment is provided with a first resistor 33, a second resistor, a first circuit chip 34 and a second circuit chip, as the electronic components. The first circuit chip 34 and the second circuit chip each include a drive circuit or the like for adjusting the gate voltage. Although not shown, the second resistor is disposed along the Y-axis direction from the first resistor 33. Similarly, although not shown, the second circuit chip is disposed along the Y-axis direction from the first circuit chip 34.

The first resistor 33 and the first circuit chip 34 are disposed on the insulating heat dissipation sheet 10. Specifically, the first resistor 33 and the first circuit chip 34 are disposed on the side opposite to the second heat sink 22, with respect to the first heat sink 21 interposed between them. Although not specifically shown, the second resistor and the second circuit chip are disposed on the insulating heat dissipation sheet 10, and are located on the side opposite to the second heat sink 22 with respect to the first heat sink 21 interposed therebetween in the X-axis direction, in a similar manner to the first resistor 33 and the first circuit chip 34. As described above, the first resistor 33 and the second resistor are arranged side by side in the Y-axis direction, and the first circuit chip 34 and the second circuit chip are arranged side by side in the Y-axis direction. In addition, the first resistor 33, the second resistor, the first circuit chip 34, and the second circuit chip are arranged in the portions of the insulating heat dissipation sheet 10 facing the first connection pipe 911, similar to the first heat sink 21 and the second heat sink 22.

One end of the first resistor 33 is connected to the first gate wiring portion first wiring layer 141a through a first resistor first via 541a, which is disposed in a first resistor first via hole 541 formed in the first encapsulating member 51. The other end of the first resistor 33 is connected to a first connection wiring portion wiring layer 171a disposed on the first encapsulating member 51 through a second resistor second via 542a, which is disposed in a first resistor second via hole 542 formed in the first encapsulating member 51.

One end of the first circuit chip 34 is connected to the first connection wiring portion wiring layer 171a through a first circuit chip first via 543a, which is disposed in a first circuit chip first via hole 543 formed in the first encapsulating member 51. The other end of the first circuit chip 34 is connected to a first circuit chip wiring layer 181a through a first circuit chip second via 544a, which is disposed in a first circuit chip second via hole 544 formed in the first encapsulating member 51.

One end of the second resistor is connected to the second gate wiring portion first wiring layer 151a through a second resistor first via 545a, which is disposed in a second resistor first via hole 545 formed in the first encapsulating member 51. The other end of the second resistor is connected to a second connection wiring portion wiring layer 172a disposed on the first encapsulating member 51 through a second resistor second via 546a, which is disposed in a second resistor second via hole 546 formed in the first encapsulating member 51.

One end of the second circuit chip is connected to the second connection wiring portion wiring layer 172a through a second circuit chip first via 547a, which is disposed in a second circuit chip second via hole 547 formed in the first encapsulating member 51. The other end of the second circuit chip is connected to a second circuit chip wiring layer 182a through a second circuit chip second via 548a, which is disposed in a second circuit chip second via hole 548 formed in the first encapsulating member 51.

The third wiring portion second wiring layer 131b, which is formed on the second encapsulating member 52, extends outward from the portion facing the first semiconductor chip 31 beyond the portions facing the first connection wiring portion wiring layer 171a, the first circuit chip wiring layer 181a, the second connection wiring portion wiring layer 172a, and the second circuit chip wiring layer 182a in the X-axis direction. The third wiring portion second wiring layer 131b is formed with a first hole 1311 at the portion facing the first connection wiring portion wiring layer 171a and the first circuit chip wiring layer 181a. The third wiring portion second wiring layer 131b is formed with a second hole 1312 at the portion facing the second connection wiring portion wiring layer 172a and the second circuit chip wiring layer 182a. The first hole 1311 and the second hole 1312 are formed at the portions facing the second connection pipe 912. In the present embodiment, an example in which the first hole 1311 and the second hole 1312 are formed separately is illustrated. Alternatively, the first hole 1311 and the second hole 1312 may be connected to each other.

A first common heat dissipation wiring layer 191b and a first circuit chip heat dissipation wiring layer 192b are formed within the first hole 1311 on the second encapsulating member 52. In addition, a second common heat dissipation wiring layer 193b and a second circuit chip heat dissipation wiring layer 194b are formed within the second hole 1312 on the second encapsulating member 52. In other words, the first common heat dissipation wiring layer 191b, the first circuit chip heat dissipation wiring layer 192b, the second common heat dissipation wiring layer 193b, and the second circuit chip heat dissipation wiring layer 194b are formed at the portions facing the second connection pipe 912. In the present embodiment, the first common heat dissipation wiring layer 191b, the first circuit chip heat dissipation wiring layer 192b, the second common heat dissipation wiring layer 193b, and the second circuit chip heat dissipation wiring layer 194b correspond to electronic component heat dissipation wiring layers.

The first common heat dissipation wiring layer 191b is connected to the first connection wiring portion wiring layer 171a through a first common heat dissipation via 527a, which is disposed in a first common heat dissipation via hole 527 formed in the second encapsulating member 52. The first circuit chip heat dissipation wiring layer 192b is connected to the first circuit chip wiring layer 181a through a first circuit chip via 528a, which is disposed in a first circuit chip via hole 528 formed in the second encapsulating member 52.

The second common heat dissipation wiring layer 193b is connected to the second connection wiring portion wiring layer 172a through a second common heat dissipation via 529a, which is disposed in a second common heat dissipation via hole 529 formed in the second encapsulating member 52. The second circuit chip heat dissipation wiring layer 194b is connected to the second circuit chip wiring layer 182a through a second circuit chip via 530a, which is disposed in a second circuit chip via hole 530 formed in the second encapsulating member 52.

Further, the first gate wiring portion second wiring layer 141b and the second gate wiring portion second wiring layer 151b are disposed on the side opposite to the first wiring portion second wiring layer 111b with respect to the third wiring portion second wiring layer 131b interposed therebetween in the X-axis direction. Specifically, the first gate wiring portion second wiring layer 141b is formed at a position facing the end of the first circuit chip wiring layer 181a on the side opposite to the first circuit chip 34. The, the first gate wiring portion second wiring layer 141b is connected to the first circuit chip wiring layer 181a through the first gate via 524a. Similarly, the second gate wiring portion second wiring layer 151b is formed at a position facing the end of the second circuit chip wiring layer 182a on the side opposite to the second circuit chip. The second gate wiring portion second wiring layer 151b is connected to the second circuit chip wiring layer 182a through the second gate via 525a.

According to the present embodiment described above, the first semiconductor chip 31 is disposed on the first heat sink 21 and is thermally connected to the first heat dissipation wiring layer 161b. The second semiconductor chip 32 is disposed on the second heat sink 22 and is thermally connected to the second heat dissipation wiring layer 162b. Therefore, the similar effects to those of the first embodiment described above can be achieved.

(1) In the present embodiment, the semiconductor module 1 includes the first resistor 33, the first circuit chip 34, the second resistor, and the second circuit chip, as the electronic components. The first resistor 33, the first circuit chip 34, the second resistor, and the second circuit chip are disposed on the portions of the insulating heat dissipation sheet 10 facing the first connection pipe 911. As a result, heats generated from the first resistor 33, the first circuit chip 34, the second resistor, and the second circuit chip are dissipated from the other surface 1b side of the semiconductor module 1 toward the first connection pipe 911. Further, the semiconductor module 1 has the first common heat dissipation wiring layer 191b, which is thermally connected to the first resistor 33 and the first circuit chip 34, as well as the first circuit chip heat dissipation wiring layer 192b, which is thermally connected to the first circuit chip 34. The semiconductor module 1 has the second common heat dissipation wiring layer 193b, which is thermally connected to the second resistor and the second circuit chip, as well as the second circuit chip heat dissipation wiring layer 194b, which is thermally connected to the second circuit chip. Therefore, the heats generated from the first resistor 33, the first circuit chip 34, the second resistor, and the second circuit chip are dissipated from the one surface 1a side of the semiconductor module 1 toward the second connection pipe 912. Namely, according to the present embodiment, a double-sided heat dissipation structure can be achieved even for the electronic components.

### Third Embodiment

A third embodiment will be described. In the present embodiment, the insulating heat dissipation sheets 10 and 60 are omitted from the electronic device S of the first embodiment, and the bonding member 930 is changed from that of the electronic device S of the first embodiment. The other configurations of the present embodiment are similar to those of the first embodiment, and therefore a description of the similar configurations will not be repeated.

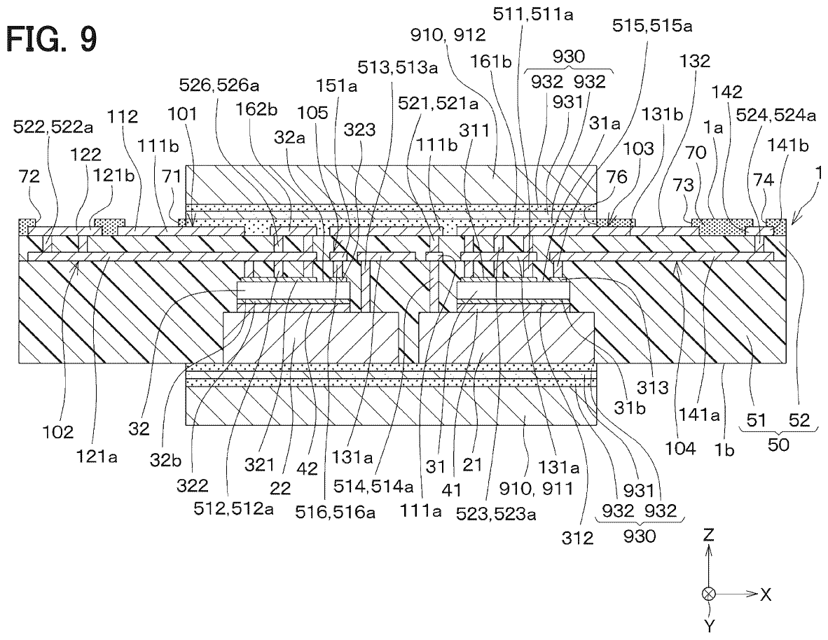

As shown in FIG. 9, in the semiconductor module 1 of the present embodiment, a protective member 70 made of a solder resist or the like is disposed on the second encapsulating member 52, instead of the insulating heat dissipation sheet 60. The protective member 70 is formed with contact holes 71 to 73 so as to expose the first to third terminal portions 112, 122, and 132. The protective member 70 is formed with a contact hole 74 so as to expose the first gate terminal portion 142. Although not specifically shown, the protective member 70 is further formed with a contact hole so as to expose the second gate terminal portion 152.

Also, the protective member 70 of the present embodiment is formed with an opening 76 in a portion facing the second connection pipe 912. Therefore, in the semiconductor module 1 of the present embodiment, the first heat dissipation wiring layer 161b, the second heat dissipation wiring layer 162b and the like are exposed. The protective member 70 is made of a material with lower heat dissipation properties than the insulating heat dissipation sheet 60 of the first embodiment described above.

The semiconductor module 1 of the present embodiment is not provided with the insulating heat dissipation sheet 10. Therefore, the other surface 1b of the semiconductor module 1 is provided by the encapsulating member 50, the first heat sink 21, and the second heat sink 22.

When arranging the semiconductor module 1 on the cooling device 9 to construct the electronic device S, the semiconductor module 1 is arranged on the cooling device 9 through the bonding member 930, which has an insulating substrate 931 sandwiched between insulating heat conductive members 932 made of grease or the like. The bonding member 930, which is disposed between the second connection pipe 912 and the semiconductor module 1, is arranged in opening 76 of the protective member 70 so that the insulating heat conductive member 932 covers the first heat dissipation wiring layer 161b, the second heat dissipation wiring layer 162b and the like, which are exposed from the protective member 70.

According to the present embodiment described above, the first semiconductor chip 31 is disposed on the first heat sink 21 and is thermally connected to the first heat dissipation wiring layer 161b. The second semiconductor chip 32 is disposed on the second heat sink 22 and is thermally connected to the second heat dissipation wiring layer 162b. Therefore, the similar effects to those of the first embodiment can be achieved.

(1) In the present embodiment, the insulating heat conductive member 932 included in the bonding member 930 is disposed so as to cover the first heat dissipation wiring layer 161b and the second heat dissipation wiring layer 162b. Therefore, the semiconductor module 1 can have a configuration in which the first heat dissipation wiring layer 161b and the second heat dissipation wiring layer 162b are exposed, thereby improving design flexibility.

### Other Embodiments

Although the present disclosure has been described in accordance with the embodiments, it is understood that the present disclosure is not limited to such embodiments or structures. The present disclosure encompasses various modifications and variations within the scope of equivalents. In addition, various combinations and configurations, as well as other combinations and configurations that include only one element, more, or less, fall within the scope and spirit of the present disclosure.

For example, in each of the embodiments described above, the second heat dissipation wiring layer 162b may be formed at a position different from the position facing the second semiconductor chip 32 as long as it faces the second connection pipe 912.

In each of the embodiments described above, the routing of the first to third wiring portions 101 to 103, the first gate wiring portion 104, and the second gate wiring portion 105 can be appropriately modified.

Furthermore, in the third embodiment described above, the type, number, configuration, and the like of the electronic components can be appropriately changed. The electronic components may be connected to only one of the first semiconductor chip 31 or the second semiconductor chip 32.

The embodiments described above can also be appropriately combined. For example, the electronic device S may be configured by combining the second embodiment and the third embodiment.

What is claimed is:

1. A semiconductor module having a first surface and a second surface opposite to the first surface in a thickness direction and is capable of being disposed on a cooling device so that the first surface and the second surface are sandwiched between at least two connection pipes of the cooling device, the semiconductor module comprising:
a first semiconductor chip and a second semiconductor chip, each formed with a switching element;
a first heat sink disposed adjacent to the second surface with respect to the first semiconductor chip, and on which the first semiconductor chip is mounted;
a second heat sink disposed adjacent to the second surface with respect to the second semiconductor chip, and on which the second semiconductor chip is mounted;
an encapsulating member encapsulating the first semiconductor chip and the second semiconductor chip;
a first heat dissipation wiring layer disposed adjacent to the first surface with respect to the first semiconductor chip and thermally connected to the first semiconductor chip; and
a second heat dissipation wiring layer disposed adjacent to the first surface with respect to the second semiconductor chip and thermally connected to the second semiconductor chip.

2. The semiconductor module according to claim 1, further comprising:
an insulating heat dissipation sheet, wherein
the insulating heat dissipation sheet provides the first surface, and
the insulating heat dissipation sheet covers the first heat dissipation wiring layer and the second heat dissipation wiring layer.

3. The semiconductor module according to claim 1, wherein
the first semiconductor chip and the second semiconductor chip are connected in series,
the semiconductor module further comprising:
a first wiring portion connected to the first semiconductor chip;
a second wiring portion connected to the second semiconductor chip; and
a third wiring portion connecting the first semiconductor chip and the second semiconductor chip, wherein
the first wiring portion, the second wiring portion, and the third wiring portion are collectively disposed on a side adjacent to the first surface with respect to the first semiconductor chip and the second semiconductor chip,
the first wiring portion and the second wiring portion have facing portions facing each other,
the encapsulating member includes:
a first encapsulating member that encapsulates the first heat sink, the second heat sink, the first semiconductor chip, and the second semiconductor chip; and
a second encapsulating member that is disposed on the first encapsulating member,
the third wiring portion has a portion that is located at a position facing the first semiconductor chip on the second encapsulating member,
the first heat dissipation wiring layer is provided by a part of the third wiring portion that faces the first semiconductor chip,
the second wiring portion includes a second wiring portion wiring layer that is disposed on the first encapsulating member,
the first wiring portion includes a first wiring portion wiring layer that is disposed on the second encapsulating member, has a portion facing the second wiring portion wiring layer, and is formed with an opening at a position facing the second semiconductor chip, and
the second heat dissipation wiring layer is disposed on the second encapsulating member and located in an opening of the first wiring portion wiring layer, and is thermally connected to the second semiconductor chip through a via disposed in the second encapsulating member and the second wiring portion wiring layer.

4. The semiconductor module according to claim 1, further comprising:
an electronic component connected to at least one of the first semiconductor chip or the second semiconductor chip; and
an electronic component heat dissipation wiring layer thermally connected to the electronic component, wherein
the electronic component is disposed adjacent to the second surface, and
the electronic component heat dissipation wiring layer is disposed adjacent to the first surface.

5. An electronic device, comprising:
a semiconductor module having a first surface and a second surface opposite to the first surface in a thickness direction, the semiconductor module including:
a first semiconductor chip and a second semiconductor chip, each formed with a switching element;
a first heat sink disposed adjacent to the second surface with respect to the first semiconductor chip, and on which the first semiconductor chip is mounted;
a second heat sink disposed adjacent to the second surface with respect to the second semiconductor chip, and on which the second semiconductor chip is mounted;
an encapsulating member encapsulating the first semiconductor chip and the second semiconductor chip;
a first heat dissipation wiring layer disposed adjacent to the first surface with respect to the first semiconductor chip and thermally connected to the first semiconductor chip; and
a second heat dissipation wiring layer disposed adjacent to the first surface with respect to the second semiconductor chip and thermally connected to the second semiconductor chip; and
a cooling device having a flow path through which a cooling medium for cooling the semiconductor module flows, wherein
the cooling device includes an inflow pipe through which the cooling medium flows in, an outflow pipe through which the cooling medium flows out, and a plurality of connection pipes connecting the inflow pipe and the outflow pipe,
the semiconductor module is disposed on the cooling device so that the first surface and the second surface are sandwiched between at least two of the connection pipes,
the first heat sink and the second heat sink are disposed at positions facing one of the at least two of the connection pipes located adjacent to the second surface, and
the first heat dissipation wiring layer and the second heat dissipation wiring layer are disposed at positions facing the other of the at least two of the connection pipes located adjacent to the first surface.

6. The electronic device according to claim 5, further comprising:
a bonding member having an insulating substrate and an insulating heat conductive member, wherein
the bonding member is disposed between the semiconductor module and the other of the at least two of the connection pipes, and
the first heat dissipation wiring layer and the second heat dissipation wiring layer are covered by the insulating heat conductive member.
